(19) United States
(12) Patent Application Publication
(10) Pub. No.: US 2023/0279580 A1
(43) Pub. Date: Sep. 7, 2023

(54) SILICON CARBIDE SINGLE CRYSTAL AND MANUFACTURING METHOD OF SILICON CARBIDE SINGLE CRYSTAL

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Akiyoshi HORIAI, Nisshin-shi (JP); Takeshi OKAMOTO, Nisshin-shi (JP); Takahiro KANDA, Nisshin-shi (JP); Norihiro HOSHINO, Chiyoda-ku (JP); Kiyoshi BETSUYAKU, Chiyoda-ku (JP); Isaho KAMATA, Chiyoda-ku (JP); Hidekazu TSUCHIDA, Chiyoda-ku (JP); Takashi KANEMURA, Nisshin-shi (JP)

(21) Appl. No.: 18/161,288

(22) Filed: Jan. 30, 2023

(30) Foreign Application Priority Data
Mar. 2, 2022 (JP) 2022-031847

(51) Int. Cl. C30B 25/10; C30B 29/36; C30B 25/16; C30B 25/14

(52) U.S. Cl. CPC C30B 25/10; C30B 25/14; C30B 25/16; C30B 29/36

(57) ABSTRACT

A manufacturing method of a silicon carbide single crystal includes growing the silicon carbide single crystal on a surface of a seed crystal by supplying a supply gas including a raw material gas of silicon carbide to the surface of the seed crystal and controlling an environment so that at least a part inside the heating vessel is 2500° C. or higher. The growing the silicon carbide single crystal includes controlling a temperature distribution ΔT in a radial direction centering on central axis of the seed crystal and the silicon carbide single crystal satisfies a radial direction temperature condition of ΔT≤10° C. on the surface of the seed crystal before the growing of the silicon carbide single crystal and on a growth surface of the silicon carbide single crystal during the growing of the silicon carbide single crystal.

### CROSS REFERENCE TO RELATED APPLICATION

The present application claims the benefit of priority from Japanese Patent Application No. 2022-031847 filed on Mar. 2, 2022. The entire disclosure of the above application is incorporated herein by reference.

### TECHNICAL FIELD

The present disclosure relates to a silicon carbide (hereinafter referred to as SiC) single crystal and a manufacturing method of a SiC single crystal.

### BACKGROUND

Conventionally, there has been known a technique to manufacture a SiC single crystal ingot by supplying a SiC raw material gas onto a surface of a seed crystal made of a SiC single crystal, and growing a SiC single crystal on the surface of the seed crystal. The SiC single crystal ingot is sliced into wafers, and the wafers are used to manufacture SiC devices.

### SUMMARY

A manufacturing method of a SiC single crystal according to an aspect of the present disclosure includes growing the SiC single crystal on a surface of a seed crystal by supplying a supply gas including a raw material gas of SiC to the surface of the seed crystal and controlling an environment so that at least a part inside the heating vessel is 2500° C. or higher. The growing the SiC crystal includes controlling a temperature distribution ΔT in a radial direction centering on central axis of the seed crystal and the SiC single crystal satisfies a radial direction temperature condition of ΔT≤10° C. on the surface of the seed crystal before the growing of the SiC single crystal and on a growth surface of the SiC single crystal during the growing of the SiC single crystal.

A SiC single crystal according to another aspect of the present disclosure includes a seed crystal, and a grown SiC single crystal that is grown on a surface of the seed crystal. The grown SiC single crystal has a basal plane dislocation (BPD) density that is lower than a BPD density of the seed crystal, and the BPD density of the grown SiC single crystal decreases along a direction away from the seed crystal.

A SiC single crystal according to another aspect of the present disclosure is grown on a seed crystal with a C-plane as a growth surface and a Si-plane as a surface opposite to the growth surface. The SiC single crystal includes a portion close to the C-plane and a portion close to the Si-plane, and the portion close to the C-plane has a BPD density that is lower than a BPD density of the portion close to the Si-plane.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view illustrating a manufacturing apparatus used for manufacturing a SiC single crystal according to a first embodiment;

FIG. 2 is a diagram showing a radial temperature distribution ΔT centering on central axis of a seed crystal and the SiC single crystal;

FIG. 3 is a diagram showing a relationship between a temperature distribution ΔT and a shear stress ┬ generated on a basal plane of the seed crystal or the SiC single crystal;

FIG. 4 is a diagram showing changes in basal plane dislocation (BPD) density in the seed crystal at an initial stage of a growth of a SiC single crystal and after the growth is completed; and

FIG. 5 is a diagram showing changes in BPD density in a growth direction of the SiC single crystal.

### DETAILED DESCRIPTION

To begin with, a relevant technology will be described only for understanding embodiments of the present disclosure.

The quality of a SiC device is affected by a dislocation density of a SiC substrate. Although a SiC single crystal ingot can be obtained by crystal growth on a surface of a seed crystal, the SiC single crystal ingot may include dislocations due to impurities at an initial stage of growth and dislocations due to a stress generated by a difference in thermal properties between the seed crystal and a pedestal on which the seed crystal is attached. Thus, in the SiC single crystal ingot obtained after growth, a BPD density may be increased in a growth direction of the SiC single crystal.

In order to restrict threading dislocations that can change to BPDs, a crystal temperature distribution and a stress can be controlled. For example, in a sublimation method, a seed crystal having a thickness of 2.0 mm or more may be used in order to solve an issue that a deterioration of the seed crystal is caused by thermal decomposition of the seed crystal, especially macro defects generated by the thermal decomposition of an outer peripheral portion of the seed crystal.

However, in a gas growth method in which a SiC single crystal is grown at a higher temperature than the sublimation method, an influence of etching due to thermal decomposition is larger than that in the sublimation method. Therefore, even if a thickness of a seed crystal is set to 2 mm or more, robustness of a growth condition control of a SiC single crystal may be insufficient, and a SiC single crystal having a desired BPD density may not be obtained.

A manufacturing method of a SiC single crystal according an aspect of the present disclosure includes arranging a seed crystal in a heating vessel that has a hollow portion forming a reaction chamber, and growing the SiC single crystal on a surface of the seed crystal by supplying a supply gas including a raw material gas of SiC to the surface of the seed crystal and controlling an environment so that at least a part inside the heating vessel is 2500° C. or higher. The growing the SiC single crystal includes controlling a temperature distribution ΔT in a radial direction centering on central axis of the seed crystal and the SiC single crystal satisfies a radial direction temperature condition of ΔT≤10° C. on the surface of the seed crystal before the growing of the SiC single crystal and on a growth surface of the SiC single crystal during the growing of the SiC single crystal.

In the manufacturing method described above, when growing the SiC single crystal by supplying the SiC raw material gas containing Si and C in the environment where at least a part inside the heating vessel is 2500° C. or higher, the radial direction temperature condition is set so that the temperature distribution ΔT satisfies a relationship of ΔT≤10° C. In other words, although the thickness of the SiC single crystal changes along with growth of the SiC single crystal, the temperature difference in the radial direction of the SiC single crystal is set to 10° C. or less at any thickness. As a result, a shear stress ┬ generated in a basal plane of the seed crystal or the SiC single crystal during growth of the SiC single crystal can be reduced to 1.4 MPa or less. Therefore, it is possible to restrict an increase in BPD density, and a SiC single crystal suitable for manufacturing a high-quality SiC device can be obtained.

A SiC single crystal according to another aspect of the present disclosure includes a seed crystal and a grown SiC single crystal that is grown on a surface of the seed crystal. The grown SiC single crystal has a BPD density that is lower than a BPD density of the seed crystal, and the BPD density of the SiC single crystal decreases along a direction away from the seed crystal.

In a case where the BPD density of the grown SiC single crystal is less than the BPD density of the seed crystal, and the BPD density of the grown SiC single crystal decreases along a direction away from the seed crystal as described above, the grown SiC single crystal can be more suitable for manufacturing a high-quality SiC device with the progress of growth.

A SiC single crystal according to another aspect of the present disclosure is grown on a seed crystal with a C-plane as a growth surface and a Si-plane as a surface opposite to the growth surface. The SiC single crystal includes a portion close to the C-plane and a portion close to the Si-plane, and the portion close to the C-plane has a BPD density that is lower than a BPD density of the portion close to the Si-plane.

In a case where the SiC single crystal is grown on the seed crystal with the C-plane as the growth surface, and the BPD density of the portion close to the C-plane is lower than the BPD density of the portion close to the Si-plane as described above, the SiC single crystal can be more suitable for manufacturing a high-quality SiC device with the progress of growth.

Embodiments of the present disclosure will be described hereinafter with reference to the drawings. In the embodiments described hereinafter, the same or equivalent parts will be designated with the same reference numerals.

### First Embodiment

First, a SiC single crystal manufacturing apparatus used for manufacturing a SiC single crystal according to a first embodiment will be described.

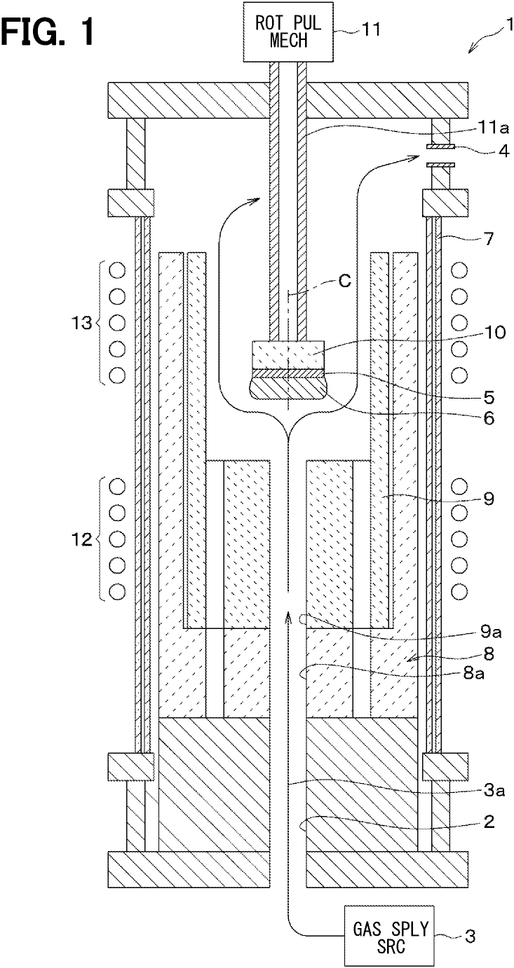

A SiC single crystal manufacturing apparatus 1 shown in FIG. 1 is used for manufacturing a SiC single crystal ingot by long growth, and is installed so that a vertical direction of a paper plane of FIG. 1 corresponds to a vertical direction.

Specifically, the SiC single crystal manufacturing apparatus 1 causes a supply gas 3a containing a SiC raw material gas from a gas supply source (GAS SPLY SRC) 3 to flow in through a gas supply port 2, and causes an unreacted gas to be exhausted through a gas exhaust port 4, thereby growing a SiC single crystal 6 on a seed crystal 5 formed of a SiC single crystal substrate.

The SiC single crystal manufacturing apparatus 1 includes the gas supply source 3, a vacuum chamber 7, a heat insulating member 8, a heating vessel 9, a pedestal 10, a rotary pulling mechanism (ROT PUL MECH) 11, and first and second heating devices 12 and 13.

The gas supply source 3 supplies a supply gas 3a that includes at least a SiC raw material gas containing Si and C, for example, a mixed gas of a silane-based gas such as silane and a hydrocarbon-based gas such as propane, from the gas supply port 2 having a cylindrical shape. The gas supply source 3 and the like form a gas supply mechanism for supplying the SiC raw material gas to the seed crystal 5 from below.

The gas supply source 3 has only to supply at least the SiC raw material gas as the supply gas 3a. However, when the gas supply source 3 supplies the SiC raw material gas with a carrier gas, it is possible to dilute the SiC raw material gas to increase a flow rate or adjust a concentration of the SiC raw material gas. The gas supply source 3 can supply an etching gas instead of or in addition to the carrier gas. When the gas supply source 3 supplies the etching gas, it is possible to restrict adhesion of by-products to locations where adhesion is not desired, in addition to adjusting the flow rate and the concentration of the SiC raw material gas. As the carrier gas, an inert gas such as He, Ar, and the like can be used. As the etching gas, H₂, HCl, and the like can be used. Furthermore, when introducing a dopant into the SiC single crystal 6 to be grown, an N source that becomes an n-type dopant such as N₂ (nitrogen) can also be introduced. Not only an n-type dopant such as the N source, but also an Al (aluminum) source and a B (boron) source, which are p-type dopants, can be introduced.

The vacuum chamber 7 is made of quartz glass or the like, has a tube shape providing a hollow portion, in the present embodiment, a cylindrical shape, and is structured so that the supply gas 3a can be introduced and exhausted. The vacuum chamber 7 accommodates other components of the SiC single crystal manufacturing apparatus 1, and is configured to be able to reduce a pressure by vacuum drawing in an accommodated internal space. The gas supply port 2 for the supply gas 3a is disposed at a bottom of the vacuum chamber 7, and the gas exhaust port 4 is disposed at an upper position of a side wall of the vacuum chamber 7.

The heat insulating member 8 has a tube shape providing a hollow portion, in the present embodiment, a bottomed cylindrical shape, and is disposed coaxially with the vacuum chamber 7. The heat insulating member 8 has a cylindrical shape portion having a diameter smaller than a diameter of the vacuum chamber 7, and is disposed inside the vacuum chamber 7, thereby inhibiting a heat transfer from a space inside the heat insulating member 8 to the vacuum chamber 7. The heat insulating member 8 is made of, for example, graphite alone or graphite whose surface is coated with a high-melting point metal carbide such as TaC (tantalum carbide) or NbC (niobium carbide), and is hardly subjected to thermal etching.

The heat insulating member 8 has an introduction hole 8a at a center of the bottom of the heat insulating member 8. The introduction hole 8a penetrates through the bottom of the heating insulating member 8 and is connected to the gas supply port 2 so that the supply gas 3a introduced from the gas supply port 2 is introduced into the heat insulating member 8 through the introduction hole 8a.

The heating vessel 9 forms a crucible that serves as a reaction chamber, and has a tubular shape with a hollow portion, in the present embodiment, a bottomed cylindrical shape. The hollow portion of the heating vessel 9 forms a reaction chamber in which the SiC single crystal 6 is grown on a surface of the seed crystal 5. The heating vessel 9 is made of, for example, graphite alone or graphite whose surface is coated with a high-melting point metal carbide such as TaC or NbC, and is hardly subjected to thermal etching. The heating vessel 9 is disposed so as to surround the pedestal 10. The heating vessel 9 decomposes the SiC raw material gas by the time the supply gas 3a from the gas supply port 2 is led to the seed crystal 5.

The heating vessel 9 has an introduction hole 9a at the center of a bottom of the heating vessel 9. The introduction hole 9a penetrates through the bottom of the heating vessel 9 and is connected to the gas supply port 2 and the introduction hole 8a so that the supply gas 3a introduced from the gas supply port 2 and the introduction hole 8a is introduced into the heating vessel 9 through the introduction hole 9a.

The pedestal 10 is a member on which the seed crystal 5 is disposed. One surface of the pedestal 10 on which the seed crystal 5 is disposed has a shape corresponding to the shape of seed crystal 5. The pedestal 10 is disposed so that the central axis of the pedestal 10 is coaxial with the central axis of the heating vessel 9 and the central axis of a shaft 11a of the rotary pulling mechanism 11, which will be described later. In the present embodiment, by forming the pedestal 10 with a cylindrical member having the same diameter as the seed crystal 5, the one surface on which the seed crystal 5 is disposed has a circular shape. The pedestal 10 is made of, for example, graphite alone or graphite whose surface is coated with a high-melting point metal carbide such as TaC or NbC, and is hardly subjected to thermal etching.

The seed crystal 5 is attached to the one surface of the pedestal 10 facing the gas supply port 2, and the SiC single crystal 6 is grown on the surface of the seed crystal 5. Further, the pedestal 10 is connected to the shaft 11a in a surface opposite to the surface on which the seed crystal 5 is disposed, is rotated with the rotation of the shaft 11a, and can be pulled upward of the paper plane while the shaft 11a is pulled up.

The rotary pulling mechanism 11 rotates and pulls up the pedestal 10 through the shaft 11a formed of a pipe member or the like. In the present embodiment, the shaft 11a is formed in a straight line extending up and down, and one end of the shaft 11a is connected to the surface of the pedestal 10 opposite to the surface on which the seed crystal 5 is attached, and the other end of the shaft 11a is connected to a main body of the rotary pulling mechanism 11. The shaft 11a is also made of, for example, graphite alone or graphite whose surface is coated with a high-melting point metal carbide such as TaC or NbC, and is hardly subjected to thermal etching. With the above configuration, the pedestal 10, the seed crystal 5, and the SiC single crystal 6 can be rotated and pulled up, so that a growth surface of the SiC single crystal 6 can have a desired temperature distribution, and a temperature of the growth surface can be adjusted to a temperature suitable for growth along with the growth of the SiC single crystal 6.

Each of the first heating device 12 and the second heating device 13 includes a heating coil such as an induction heating coil and a direct heating coil, and is arranged so as to surround the vacuum chamber 7 to heat the heating vessel 9. In the present embodiment, each of the first heating device 12 and the second heating device 13 includes an induction heating coil. The first heating device 12 and the second heating device 13 are configured to be capable of independently controlling the temperature of a target location. The first heating device 12 is disposed at a position corresponding to the heating vessel 9, and the second heating device 13 is disposed at a position corresponding to the pedestal 10. Therefore, the temperature of the lower portion of the heating vessel 9 can be controlled by the first heating device 12 to heat and decompose the SiC raw material gas. In addition, the temperature around the pedestal 10, the seed crystal 5, and the SiC single crystal 6 can be controlled to a temperature suitable for growing the SiC single crystal 6 by the second heating device 13. In the present embodiment, a heating device includes the first heating device 12 and the second heating device 13. However, the heating device may include only the first heating device 12, or the locations of these devices may be changed as appropriate.

The SiC single crystal manufacturing apparatus 1 according to the present embodiment is configured as described above. Subsequently, a manufacturing method of the SiC single crystal 6 using the SiC single crystal manufacturing apparatus 1 according to the present embodiment will be described.

First, the seed crystal 5 is attached to the one surface of the pedestal 10. As the seed crystal 5, an off-substrate is prepared. In the off substrate, one surface has a predetermined off angle such as 4 degrees or 8 degrees with respect to a Si plane, and the other surface opposite to the one surface has the predetermined off angle with respect to a C plane, more specifically, a (000-1) C plane. The seed crystal 5 is attached to the pedestal 10 in such a manner that the one surface close to the Si plane faces the pedestal 10 and the other surface close to the C plane is disposed opposite from the pedestal 10 so as to be a growth surface of the SiC single crystal 6.

Subsequently, the pedestal 10 and the seed crystal 5 are disposed in the heating vessel 9. Then, the heating vessel 9 is heated by controlling the first heating device 12 and the second heating device 13 to obtain a desired temperature distribution. In other words, the temperature distribution is controlled such that the SiC raw material gas contained in the supply gas 3a is heated and decomposed to be supplied to the surface of the seed crystal 5, and the SiC raw material gas is recrystallized on the surface of the seed crystal 5, while a sublimation rate is higher than a recrystallization rate in the heating vessel 9. Specifically, at least a part of the inside of the heating vessel 9 is set to a temperature of 2500° C. or higher. For example, the temperature of the bottom of the heating vessel 9 is set to about 2800±100° C., and the temperature of the surface of the seed crystal 5 is set to about 2500±100° C.

Further, the supply gas 3a containing the SiC raw material gas is introduced through the gas supply port 2 while maintaining a desired pressure in the vacuum chamber 7. The partial pressure of the silane-based gas such as silane and the hydrocarbon-based gas is adjusted to match the temperature. In addition, if necessary, a carrier gas of an inert gas such as He or Ar or an etching gas such as H₂ or HCl is introduced, and the flow rate and the concentration of the raw material gas are adjusted so that by-products are less likely to be generated. Accordingly, the supply gas 3a flows as shown by the arrows in FIG. 1 and is supplied to the seed crystal 5, and the SiC single crystal 6 is grown on the surface of the seed crystal 5 by the source gas included in the supply gas 3a.

Then, the rotary pulling mechanism 11 pulls up the pedestal 10, the seed crystal 5, and the SiC single crystal 6 in accordance with the growth rate of the SiC single crystal 6 while rotating them through the shaft 11a. As a result, a height of the growth surface of the SiC single crystal 6 is kept substantially constant, and the temperature distribution of the growth surface temperature can be controlled with high controllability.

Here, when growing the SiC single crystal 6, regarding a temperature distribution of the seed crystal 5 before growth and a temperature distribution on the growth surface of the SiC single crystal 6 during growth, a temperature distribution ΔT in a radial direction centering on a central axis C of the seed crystal 5 and the SiC single crystal 6 is set to satisfy a relationship of ΔT≤10° C. Hereinafter, the condition of the temperature distribution ΔT in the radial direction centering on the central axis C of the seed crystal 5 and the SiC single crystal 6 is referred to as a radial direction temperature condition. In the present embodiment, the central axis C of the seed crystal 5 and the SiC single crystal 6 indicates an axis passing through the center of the seed crystal 5 and the center of the SiC single crystal 6 on planes perpendicular to the vertical direction of FIG. 1 and extending along the growth direction of the SiC single crystal 6.

As described above, in the sublimation method, the thickness of the seed crystal may be set to 2.0 mm or more in order to restrict the disappearance of the seed crystal at the outer peripheral portion due to thermal decomposition. However, the robustness of growth condition control is insufficient in a gas growth method in which a SiC single crystal is grown at a higher temperature than the sublimation method. Also in the present embodiment, it is effective to set the thickness of the seed crystal 5 to 2.0 mm or more. However, it is important to reduce the stress applied to the SiC single crystal 6 at any stage of the growth and the increase in thickness of the SiC single crystal 6 in order to reduce the BPD density. In addition, the BPD density in the seed crystal 5 increases due to the stress generated when the SiC single crystal 6 is grown, which is one of the causes of the increase in the BPD density of the SiC single crystal 6. Thus, it is also necessary to restrict the increase in the BPD density in the seed crystal 5 during the growth of the SiC single crystal 6.

As a result of diligent studies by the present inventors, it was found that the increase in the BPD density of the SiC single crystal 6 can be restricted when the temperature distribution of the seed crystal 5 before growth and the temperature distribution on the growth surface of the SiC single crystal 6 during growth satisfy the above-described radial direction temperature condition.

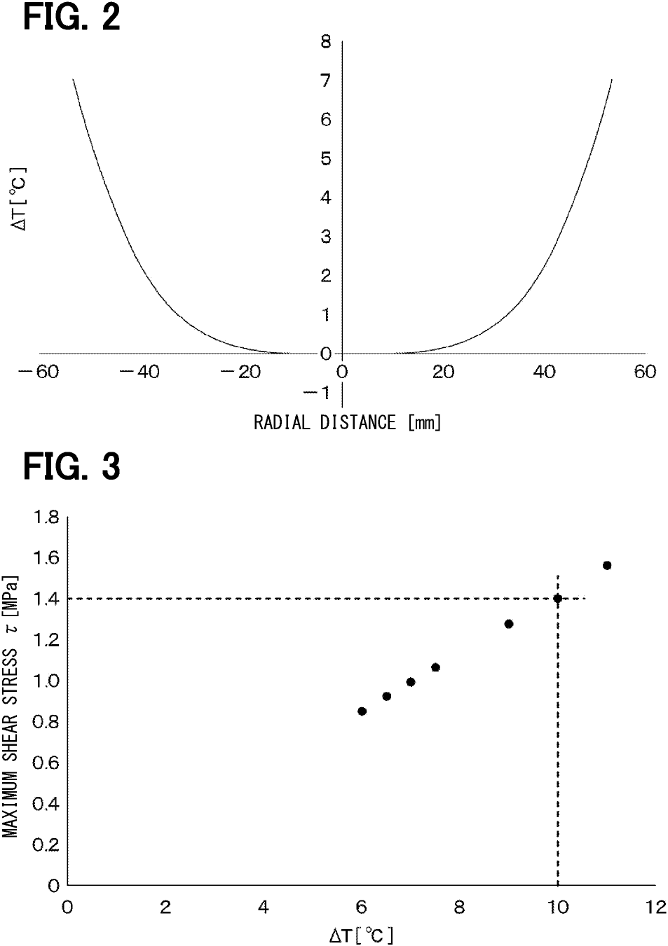

Assuming that an outer diameter of the seed crystal 5 is R, and a diameter at a position where the temperature distribution ΔT is to be measured is r, a simulation was performed about the temperature distribution of the seed crystal 5 before growth and the temperature distribution on the growth surface of the SiC single crystal 6 during growth. The temperature distribution ΔT is represented by the equation of ΔT=(r/R)m as an exponential function with r/R as the base. An index m that fits the temperature distribution calculated from a growth shape when the SiC single crystal 6 was actually grown on the surface of the seed crystal 5 was obtained, and the temperature distribution ΔT was calculated using the index m. Here, since the index m that fits the actual temperature distribution was 4, the temperature distribution ΔT was calculated with m=4. As a result, it was confirmed that the temperature distribution ΔT was represented by the graph shown in FIG. 2. Although this temperature distribution ΔT shows an example in which the diameter of the seed crystal 5 is 10.16 cm (4 inches), the same distribution is obtained even if the diameter is not this size.

As shown in FIG. 2, the temperature distribution ΔT of the seed crystal 5 before growth of the SiC single crystal 6 and the temperature distribution ΔT on the growth surface of the SiC single crystal 6 during growth in the radial direction centering on the central axis C depend on the distance from the central axis C. At a position near the central axis C to some extent, the temperature is approximately the same as the temperature at the central axis C. However, the temperature deviates from the temperature at the central axis C with increase in the distance from the central axis C. More specifically, in the temperature distribution ΔT, the deviation of the temperature from the temperature at the central axis C increases with increase in the distance from the central axis C.

The present inventors examined the relationship between the temperature distribution ΔT and the shear stress _{T} MPa generated on the basal plane of the seed crystal 5 or the SiC single crystal 6 and confirmed that the relationship was represented by the graph shown in FIG. 3. As shown in FIG. 3, when the temperature distribution ΔT exceeded 10° C., the shear stress _{T} satisfied a relationship of _{T}>1.4 MPa. According to the examination by the present inventors, it was found that the BPD density increases when the shear stress _{T} generated in the basal plane of the seed crystal 5 or the SiC single crystal 6 exceeds 1.4 MPa. Therefore, it is necessary that the relationship of shear stress _{T}≤1.4 MPa is satisfied, that is, the radial temperature condition satisfies the temperature distribution ΔT≤10° C. so as not to increase the BPD density.

Therefore, when the SiC single crystal manufacturing apparatus 1 is designed to satisfy this condition by simulation, the SiC single crystal 6 can be grown while restricting the increase in the BPD density. Factors that affect the temperature distribution ΔT include the direction and the flow rate of the gas in the SiC single crystal manufacturing apparatus 1, the heating mode by the first heating device 12 and the second heating device 13, and the like. However, it was confirmed that these are not so large factors but the shapes of the heating vessel 9 and the heat insulating member 8 are large factors. Therefore, by adjusting the shape of the heating vessel 9 and the heat insulating member 8 so that the radial direction temperature condition satisfies the temperature distribution ΔT≤10° C., it becomes possible to satisfy the relationship of shear stress _{T}≤1.4 MPa even in the outer peripheral portion of the seed crystal 5 and the SiC single crystal 6. Accordingly, the SiC single crystal 6 can be grown while restricting the increase in the BPD density.

As described above, when growing the SiC single crystal by supplying the SiC raw material gas containing Si and C in the environment where at least a part of the inside of the heating vessel is 2500° C. or higher, the radial direction temperature condition is set to satisfy the relationship of the temperature distribution ΔT≤10° C. In other words, although the thickness of the SiC single crystal 6 changes along with growth of the SiC single crystal 6, the temperature difference in the radial direction of the SiC single crystal 6 is set to 10° C. or less at any thickness.

Accordingly, the shear stress _{T} generated in the basal plane of the seed crystal 5 or the SiC single crystal 6 during growth of the SiC single crystal 6 can be reduced to 1.4 MPa or less. Therefore, it is possible to restrict the increase in the BPD density, and the SiC single crystal can be suitable for manufacturing a high-quality SiC device. By slicing the SiC single crystal 6 thus obtained, a SiC wafer with a low BPD density can be obtained. The seed crystal 5 is arranged on the pedestal 10 in such a manner that the first surface close to the Si-plane face the pedestal 10 and the second surface close to the C-plane becomes the growth surface on which the SiC single crystal 6 is grown. In the grown SiC single crystal 6 and the SiC wafer, a BPD density of a portion close to the C-plane is lower than a BPD density of a portion close to the Si-plane. That is, the SiC single crystal 6 grown from the surface of the seed crystal 5 has the BPD density lower than the BPD density of the seed crystal 5 at the initial growth position of the SiC single crystal 6 close to the seed crystal 5, and then the BPD density does not increase along the growth direction of the SiC single crystal 6, that is, the direction away from the seed crystal 5. Then, preferably, the BPD density decreases with the progress of growth of the SiC single crystal 6, and the SiC single crystal 6 can be grown without increasing the BPD density thereafter. With such a configuration, the SiC single crystal 6 can be made more suitable for manufacturing a SiC device with higher quality with the progress of growth.

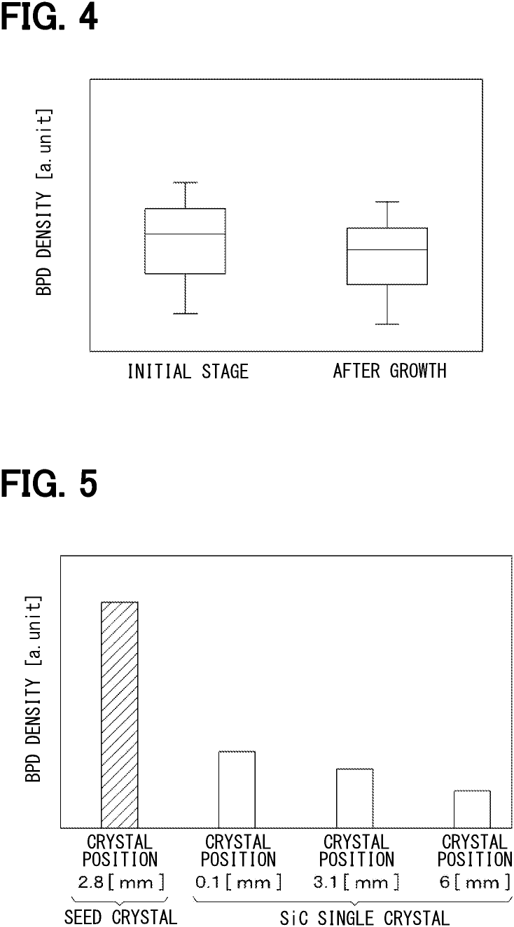

The present inventors confirmed changes in the seed crystal 5 at the initial stage of growth of the SiC single crystal 6 and after growth of the SiC single crystal 6. As a result, as shown in FIG. 4, it was confirmed that the BPD density in the seed crystal 5 after growth of the SiC single crystal 6 is similar to the BPD density in the seed crystal 5 at the initial stage of growth of the SiC single crystal 6. In this way, when the SiC single crystal 6 is grown under the above-described radial direction temperature condition, it is possible to restrict the increase in the BPD density in the seed crystal 5 as well, and it is possible to make the BPD density in the seed crystal 5 after the growth to be equal to or lower than the BPD density before the growth.

The present inventors further confirmed changes in the BPD density in the growth direction of the SiC single crystal 6 after the growth was finished. As a result, as shown in FIG. 5, the BPD density is highest at a position where a crystal position is -2.8 mm, specifically a portion inside the seed crystal 5, but the BPD density decreased with increase in the distance in the growth direction, that is, with the progress of growth. More specifically, the BPD density gradually decreased as the crystal position increased to 0.1 mm, 3.1 mm, and 6 mm. This is because when the SiC single crystal 6 is grown under the above-described radial direction temperature condition, the BPD of the seed crystal 5 is not inherited in the SiC single crystal 6, and the BPD does not increase due to the high temperature, but the BPD disappears, transforms, or is released outside the SiC single crystal 6. Thus, it is possible to restrict the increase in the BPD density of the SiC single crystal 6, and preferably to decrease the BPD density.

The SiC single crystal 6 of n-type can be obtained by introducing an N source as the supply gas 3a. The SiC single crystal 6 of n-type can be sliced into SiC wafers to be used for manufacturing power elements and the like, and is used as a substrate constituting a drain in an n-type MOSFET, for example.

The present inventors further investigated characteristics of the SiC single crystal 6 obtained as described above and the SiC wafer obtained by slicing the SiC single crystal for each of cases in which an N source was introduced as a dopant and in which no dopant was introduced. As a result, the BPD density was 1000 cm⁻² or less, and the carrier lifetime was 5 ns or less. When no dopant was introduced, the SiC single crystal 6 or SiC wafer did not contain N. When the N source was introduced as the dopant, SiC single crystals 6 and SiC wafers had an n-type impurity concentration of, for example, 5 to 9×10¹⁸ cm⁻³ or higher. The present inventors also investigated metal impurity concentrations and found that an aluminum (Al) concentration was 1×10¹¹ atoms/cm³ or less, a boron (B) concentration was 1×10¹¹ atoms/cm³ or less, a titanium (Ti) concentration was 7×10¹² atoms/cm³ or less, and a vanadium (V) concentration was 5×10¹² atoms/cm³ or less. These metal impurity concentrations are too small to obtain good device characteristics when the SiC wafer is used to form a semiconductor device.

### Other Embodiments

While the present disclosure has been described in accordance with the embodiments described above, the present disclosure is not limited to the embodiments and includes various modifications and equivalent modifications. In addition, while the various elements are shown in various combinations and configurations, which are exemplary, other combinations and configurations, including more, less or only a single element, are also within the spirit and scope of the present disclosure.

For example, the detailed structure of the SiC single crystal manufacturing apparatus 1 is merely an example, and the structure may be partially different. That is, the structures of the heating vessel 9 and the heat insulating member 8 are merely examples. The heating vessel 9 and the heating insulating member 8 may have any structures as long as the temperature distribution ΔT in the radial direction centering on the central axis C of the seed crystal 5 and the SiC single crystal 6 can be 10° C. or less.

Further, in the above embodiment, the case where the SiC single crystal 6 was grown using the seed crystal 5 having a diameter of 10.16 cm (4 inches) was exemplified as the experiment shown in FIG. 2 and FIG. 3. However, the diameter of the seed crystal 5 is only an example. That is, the diameter of the seed crystal 5 may be less than 10.16 cm or may be more than 10.16 cm. Moreover, when growing the SiC single crystal 6, it is possible to make the diameter of the SiC single crystal 6 the same as the diameter of the seed crystal 5, but the diameter of the SiC single crystal 6 may also be larger or smaller than the diameter of the seed crystal 5. However, regardless of the diameter of the SiC single crystal 6, the temperature distribution ΔT in the radial direction centering on the center axis C of the seed crystal 5 and the SiC single crystal 6 should be 10° C. or less.

Further, although FIG. 1 illustrates an ingot in which the SiC single crystal 6 is formed on the surface of the seed crystal 5, the SiC single crystal 6 may be an ingot or a wafer that is cut out.

The above-described embodiment has exemplified the SiC single crystal growth apparatus and the manufacturing method of up-flow type in which the supply gas 3a containing the SiC raw material gas is supplied to the seed crystal 5 from below. However, not limited to this example, the configuration of the gas supply mechanism may be either a side-flow type or a down-flow type as long as the radial direction temperature condition during growth satisfies the relationship of ΔT≤10° C.

What is claimed is:

1. A manufacturing method of a silicon carbide single crystal, comprising:
arranging a seed crystal in a heating vessel that has a hollow portion forming a reaction chamber; and
growing the silicon carbide single crystal on a surface of the seed crystal by supplying a supply gas including a raw material gas of silicon carbide to the surface of the seed crystal and controlling an environment so that at least a part inside the heating vessel is 2500° C. or higher, wherein
the growing the silicon carbide single crystal includes controlling a temperature distribution ΔT in a radial direction centering on a central axis of the seed crystal and the silicon carbide single crystal satisfies a radial direction temperature condition of ΔT≤10° C. on the surface of the seed crystal before the growing of the silicon carbide single crystal and on a growth surface of the silicon carbide single crystal during the growing of the silicon carbide single crystal.

2. The manufacturing method according to claim 1, wherein
the seed crystal after the growing of the silicon carbide single crystal has a basal plane dislocation density that is equal to or lower than a basal plane dislocation density of the seed crystal before the growing of the silicon carbide single crystal.

3. The manufacturing method according to claim 1, wherein
the growing the silicon carbide single crystal includes introducing a carrier gas without a nitrogen source as an n-type dopant in the supply gas.

4. The manufacturing method according to claim 1, wherein
the growing the silicon carbide single crystal includes introducing a carrier gas with a nitrogen source as an n-type dopant in the supply gas.

5. The manufacturing method according to claim 1, wherein
the growing the silicon carbide single crystal includes introducing a carrier gas with an aluminum source or a boron source as a p-type dopant in the supply gas.

6. A silicon carbide single crystal comprising:
a seed crystal; and
a grown silicon carbide single crystal that is grown on a surface of the seed crystal, wherein
the grown silicon carbide single crystal has a basal plane dislocation density that is lower than a basal plane dislocation density of the seed crystal, and
the basal plane dislocation density of the grown silicon carbide single crystal decreases along a direction away from the seed crystal.

7. The silicon carbide single crystal according to claim 6, wherein
the grown silicon carbide single crystal has an n-type impurity concentration of 5×10¹⁸ cm⁻³ or more.

8. The silicon carbide single crystal according to claim 6, wherein
the basal plane dislocation density of the grown silicon carbide single crystal is 1000 cm⁻² or less, and
the grown silicon carbide single crystal has a carrier life time of 5 ns or less, an aluminum concentration of 1×10¹¹ atoms/cm³ or less, a boron concentration of 1×10¹¹ atoms/cm³ or less, a titanium concentration of 7×10¹² atoms/cm³ or less, and a vanadium concentration of 5×10¹² atoms/cm³ or less.

9. A silicon carbide single crystal grown on a seed crystal with a C-plane as a growth surface and a Si-plane as a surface opposite to the growth surface, the silicon carbide single crystal comprising:
a portion close to the C-plane; and
a portion close to the Si-plane, wherein
the portion close to the C-plane has a basal plane dislocation density that is lower than a basal plane dislocation density of the portion close to the Si-plane.

10. The silicon carbide single crystal according to claim 9, wherein
the silicon carbide single crystal has an n-type impurity concentration of 5×10¹⁸ cm⁻³ or more.

11. The silicon carbide single crystal according to claim 9, wherein
the basal plane dislocation density of the portion close to the C-plane and the basal plane dislocation density of the portion close to the Si-plane are 1000 cm⁻² or less, and
the silicon carbide single crystal has a carrier life time of 5 ns or less, an aluminum concentration of 1×10¹¹ atoms/cm³ or less, a boron concentration of 1×10¹¹ atoms/cm³ or less, a titanium concentration of 7×10¹² atoms/cm³ or less, and a vanadium concentration of 5×10¹² atoms/cm³ or less.
